(19) United States
(12) Patent Application Publication
(10) Pub. No.: US 2026/0255718 A1
(43) Pub. Date: Aug. 27, 2026

(54) ELECTRICAL FIELD-ASSISTED ULTRAFAST DOPING IN THE POLYCRYSTALLINE CDTE SOLAR TECHNOLOGY

(71) Applicant: Feng YAN, Chandler, AZ (US)

(72) Inventor: Feng YAN, Chandler, AZ (US)

(73) Assignee: ARIZONA BOARD OF REGENTS ON BEHALF OF ARIZONA STATE UNIVERSITY, Scottsdale, AZ (US)

(21) Appl. No.: 19/547,566

(22) Filed: Feb. 23, 2026

Related U.S. Application Data
(60) Provisional application No. 63/763,138, filed on Feb. 25, 2025.

(51) Int. Cl. H10F 71/00

(52) U.S. Cl. CPC H10F 71/1253; H10F 71/128

(57) ABSTRACT

Methods are disclosed for selectively doping grain boundaries in polycrystalline chalcogenide thin films for photovoltaic applications. In some embodiments, a chalcogenide-based or cadmium-based polycrystalline substrate is treated with a chloride-containing solution and contacted with an electrolyte comprising at least one dopant. An electric field is applied such that the dopant is selectively driven into grain-boundary regions while limiting dopant incorporation within grain interiors. In some embodiments, excess dopant material is removed from a surface of the substrate, followed by a thermal treatment to diffuse dopant material into grain interiors. The methods may be applied to CdTe or CdSeTe thin films and to group V dopants.

### RELATED APPLICATIONS

This application claims the benefit of U.S. Provisional Patent Application No. 63/763,138, filed Feb. 25, 2025, titled “ELECTRICAL FIELD-ASSISTED ULTRAFAST DOPING IN POLYCRYSTALLINE CHALCOGENIDES FOR SOLAR TECHNOLOGY APPLICATIONS,” the entirety of the disclosure of which is hereby incorporated by this reference.

### TECHNICAL FIELD

This disclosure relates to electric-field-assisted doping methods, materials, and fabrication processes for polycrystalline chalcogenide semiconductor thin-film photovoltaic devices, including CdTe and CdSeTe solar cells.

### BACKGROUND

Thin-film photovoltaic technologies based on polycrystalline chalcogenide semiconductors have attracted significant interest due to their potential for high efficiency, scalable manufacturing, and reduced material usage. Among these technologies, cadmium telluride (CdTe) and related cadmium selenide telluride (CdSeTe) absorber materials have demonstrated favorable optoelectronic properties and have been incorporated into commercially deployed solar devices.

In polycrystalline chalcogenide absorber layers, the presence of grains and grain boundaries influences charge carrier generation, transport, and recombination. While grain boundaries may contribute to certain beneficial effects in polycrystalline films, they may also serve as recombination centers that limit device performance, particularly with respect to open-circuit voltage and overall power-conversion efficiency. As device architecture and performance targets advance, control over dopant distribution within polycrystalline films has become increasingly important.

Conventional doping approaches for chalcogenide thin films often rely on thermal diffusion processes that introduce dopants broadly throughout the film or from a surface region. Such approaches may require elevated temperatures and extended processing times, and may result in non-uniform dopant distributions, unintended surface accumulation, or limited dopant activation at grain boundaries. In some cases, these effects can complicate back-contact formation, introduce resistive interfacial layers, or reduce long-term device stability.

Efforts to selectively modify grain boundary properties have highlighted the potential advantages of concentrating dopants or passivating species at grain boundaries while limiting excessive incorporation within grain interiors or at exposed surfaces. However, existing techniques for achieving such selective modification may lack sufficient spatial control, process speed, or compatibility with scalable manufacturing environments.

Accordingly, there remains a need for improved methods that enable controlled, selective introduction of dopants into grain boundary regions of polycrystalline chalcogenide thin films. There is further a need for techniques that can reduce processing time, enhance dopant activation, minimize undesirable surface deposition, and support subsequent thermal treatments that promote beneficial dopant redistribution without degrading film quality or device interfaces.

### SUMMARY

According to some embodiments, a method of making a thin film for a solar cell includes treating a chalcogenide-based polycrystalline substrate with a solution that contains a chloride compound. According to some embodiments, the method further includes contacting the chalcogenide-based polycrystalline substrate with an electrolyte that contains at least one dopant and applying an electric field to the chalcogenide-based polycrystalline substrate such that the at least one dopant is selectively disposed in grain boundaries of the chalcogenide-based polycrystalline substrate. According to some embodiments, the method further includes heating the chalcogenide-based polycrystalline substrate for a duration of from one second to one hour, thereby diffusing the at least one dopant from the grain boundaries to grain interiors of the chalcogenide-based polycrystalline substrate.

According to some embodiments, the chalcogenide-based polycrystalline substrate includes cadmium telluride (CdTe) or cadmium selenide telluride (CdSeTe). According to some embodiments, the chloride compound includes CdCl₂. According to some embodiments, the at least one dopant includes arsenic, phosphorus, antimony, bismuth, copper, or combinations thereof. According to some embodiments, the chalcogenide-based polycrystalline substrate includes CdSeTe and the chloride compound includes CdCl₂.

According to some embodiments, a method of making a thin film includes treating a cadmium-based polycrystalline substrate with a solution that contains a chloride compound, contacting the cadmium-based polycrystalline substrate with an electrolyte that contains at least one dopant, applying an electric field to the cadmium-based polycrystalline substrate such that the at least one dopant is selectively disposed in grain boundaries of the cadmium-based polycrystalline substrate, and heating the cadmium-based polycrystalline substrate to diffuse the at least one dopant from the grain boundaries to grain interiors of the cadmium-based polycrystalline substrate.

According to some embodiments, the at least one dopant includes arsenic, phosphorus, antimony, bismuth, copper, or combinations thereof. According to some embodiments, the cadmium-based polycrystalline substrate includes CdTe and the chloride compound includes CdCl₂. According to some embodiments, the cadmium-based polycrystalline substrate includes CdSeTe. According to some embodiments, the cadmium-based polycrystalline substrate includes a chalcogenide. According to some embodiments, the cadmium-based polycrystalline substrate is heated at a temperature between 200° C. and 400° C. According to some embodiments, heating the cadmium-based polycrystalline substrate is performed for a duration of from one second to one hour.

According to some embodiments, a method of selectively doping grain boundaries in a polycrystalline chalcogenide thin film includes treating a polycrystalline chalcogenide substrate with a chloride-containing solution, contacting the polycrystalline chalcogenide substrate with an electrolyte that contains at least one dopant, and applying an electric field across the polycrystalline chalcogenide substrate such that the at least one dopant is driven into grain-boundary regions of the polycrystalline chalcogenide substrate. According to some embodiments, the method further includes removing excess dopant material from a surface of the polycrystalline chalcogenide substrate.

According to some embodiments, the polycrystalline chalcogenide substrate includes CdTe or CdSeTe. According to some embodiments, the at least one dopant includes arsenic, phosphorus, antimony, bismuth, copper, or combinations thereof. According to some embodiments, applying the electric field includes applying a voltage of from 0.1 to 10 volts for a duration of from 0.1 to 100 seconds. According to some embodiments, the method further includes heating the polycrystalline chalcogenide substrate after removing the excess dopant material to diffuse the dopant from the grain-boundary regions into grain interiors.

According to some embodiments, the chloride-containing solution includes CdCl₂, NaCl, MgCl₂, NH₄Cl, KCl, or combinations thereof. According to some embodiments, removing the excess dopant material includes contacting the surface with an acid, a base, or an organic solvent selected from diluted hydrochloric acid, ammonia solution, ethanol, acetone, carbon disulfide, or combinations thereof. According to some embodiments, the electrolyte includes a group V halide.

The foregoing and other aspects, features, and advantages will be apparent from the DESCRIPTION, DRAWINGS, and CLAIMS.

### BRIEF DESCRIPTION OF THE DRAWINGS

Implementations will hereinafter be described in conjunction with the appended and/or included DRAWINGS, where like designations denote like elements, and:

FIG. 1 illustrates an overview of the selective grain-boundary doping method, according to some embodiments.

FIG. 2 depicts an electrochemical cell configuration for applying an electric field across a substrate during selective grain-boundary doping, according to some embodiments.

FIG. 3 schematically shows dopant ions being preferentially driven into grain-boundary regions of a polycrystalline chalcogenide thin film and produced polycrystalline chalcogenide thin film before and after preferential doping.

FIG. 4 shows a current-voltage (J-V) curve of a CdSeTe photovoltaic device with selectively Sb doped grain boundaries.

FIG. 5A shows a surface image of a polycrystalline CdTe substrate.

FIG. 5B shows a surface image of a polycrystalline CdTe substrate after exposure to electrolytes containing Sb, according to some embodiments.

FIG. 5AC shows a surface image of a polycrystalline CdTe substrate after exposure to electrolytes containing Bi, according to some embodiments.

FIG. 6 shows X-ray diffraction (XRD) patterns representative of the crystalline structure of chalcogenide thin films treated in accordance with embodiments disclosed herein.

FIG. 7 shows a cross-sectional microstructural image showing selective localization of dopants within grain-boundary regions.

FIG. 8 schematically illustrates dopant diffusion from grain-boundary regions into grain interiors during a subsequent heating or annealing step.

FIG. 9 depicts a schematic of a thin-film photovoltaic device structure incorporating a selectively doped polycrystalline chalcogenide absorber layer formed according to the disclosed methods.

### DETAILED DESCRIPTION

The following detailed description provides numerous specific details. Those skilled in the relevant arts understand that embodiments of the disclosure may be practiced without these specific details. The disclosure may also be practiced in different and alternative configurations.

Unless specifically noted, it is intended that the words and phrases in the specification and the claims be given their plain, ordinary, and accustomed meaning to those of ordinary skill in the applicable arts. The singular forms “a,” “an,” and “the” include plural referents unless the context clearly dictates otherwise. Thus, for example, a reference to “a step” includes a reference to one or more of such steps. The words “exemplary,” “example,” “embodiment,” or various forms thereof are used herein to mean serving as an example, instance, or illustration. Any aspect or feature described herein as “exemplary” or as an “example” is not necessarily to be construed as preferred or advantageous over other aspects or designs. The examples are provided solely for purposes of clarity and understanding and do not limit or restrict the disclosure. It is to be appreciated that a myriad of additional or alternate examples of varying scope could have been presented, but have been omitted for purposes of brevity.

Throughout the description and claims of this specification, the words “comprise” and “contain” and variations of the words, for example “comprising” and “comprises”, mean “including but not limited to”, and are not intended to (and do not) exclude other components.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one. Unless otherwise indicated, materials, dopants, and process conditions described herein are illustrative and not required in all embodiments.

Thin-film photovoltaic technologies based on polycrystalline chalcogenide semiconductor materials, including cadmium telluride (CdTe) and cadmium selenide telluride (CdSeTe), have attracted significant interest due to their potential for high power-conversion efficiency, scalable manufacturing, and reduced material usage, and have been widely adopted in commercial solar cell applications. Despite substantial progress, the performance of polycrystalline CdTe and CdSeTe devices remains constrained relative to their theoretical efficiency limits. In polycrystalline CdTe and CdSeTe films, grain boundaries can contribute to improved current collection and enable high short-circuit current densities; however, grain boundaries can also act as recombination centers for photogenerated charge carriers, thereby limiting open-circuit voltage and overall device performance. Although group V dopants such as phosphorus, arsenic, antimony, and bismuth have been shown to improve p-type conductivity and device performance, existing doping approaches often require aggressive thermal treatments to drive dopants into the absorber layer, which can exacerbate back-surface doping and limit further improvements in voltage, fill factor, and device reliability.

Embodiments of the present disclosure relate to methods for selectively introducing dopants into grain boundary regions of polycrystalline chalcogenide materials using electric field-assisted electrochemical processes. The method includes contacting the polycrystalline chalcogenide with an electrolyte containing one or more dopant species and applying an electric field such that dopant incorporation is preferentially driven into grain boundary regions relative to grain interiors. The electric field promotes localized dopant migration and incorporation without reliance on extended thermal diffusion, thereby reducing undesired bulk or surface doping.

In some embodiments, the methods are applied to polycrystalline chalcogenide materials formed as thin films on a substrate. Examples include cadmium telluride (CdTe), cadmium selenide telluride (CdSeTe), and other chalcogenide semiconductor materials suitable for photovoltaic applications. The polycrystalline material includes a plurality of grains separated by grain boundary regions, with each grain including a grain interior that is structurally distinct from the surrounding grain boundaries.

“Dopant” refers to one or more elements or compounds introduced into the polycrystalline chalcogenide to modify electrical properties, including but not limited to group V elements such as phosphorus, arsenic, antimony, and bismuth, as well as copper and combinations thereof.

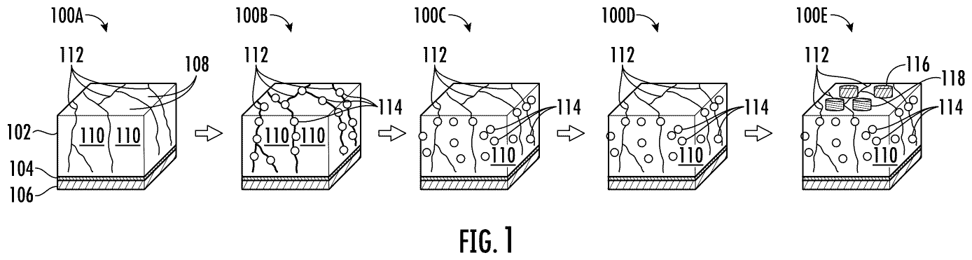

FIG. 1 illustrates an overview of a representative process flow for selectively doping grain boundaries in a polycrystalline chalcogenide material. As shown in FIGS. 1A-1E, a polycrystalline chalcogenide structure 102 is processed through successive stages. Polycrystalline chalcogenide structure 102 may be supported on an electrically conductive substrate 104 disposed on a transparent layer 106. FIG. 1 illustrates selective grain-boundary doping followed by surface treatment, thermal diffusion, and device integration.

In some embodiments, the polycrystalline chalcogenide comprises a CdCl₂-treated polycrystalline CdSeTe thin film. In representative embodiments, such a film prior to selective grain-boundary doping may exhibit a power conversion efficiency (PCE) of approximately 19%.

Polycrystalline chalcogenide structure 102 is contacted with an electrolyte comprising one or more dopant species and subjected to an applied electric field such that dopant material 114 is driven toward the polycrystalline chalcogenide. As schematically illustrated in FIG. 1B, dopant material 114 is selectively incorporated into grain-boundary regions 112 while incorporation within grain interiors 110 is limited. For example, selective grain-boundary doping of a CdCl₂-treated CdSeTe film with a group V dopant may increase PCE to approximately 20%.

Following selective grain-boundary doping, excess dopant material present at exposed surfaces of the polycrystalline chalcogenide 102 may be removed. FIG. 1C schematically illustrates the structure after surface cleaning and dopant characterization, wherein dopant material 114 remains localized within grain-boundary regions 112 while surface-deposited dopant is substantially removed.

Heating or annealing promotes diffusion of dopant material 114 from grain-boundary regions 112 into adjacent grain interiors 110, as illustrated in FIG. 1D. The selectively doped polycrystalline chalcogenide structure 102 may then be incorporated into a device structure. FIG. 1E schematically illustrates a device configuration including electrodes 116 and 118 disposed in electrical contact with the polycrystalline chalcogenide. In some embodiments, electrodes 116 and 118 comprise carbon, gold, or other conductive materials suitable for photovoltaic operation. In representative embodiments, incorporation of the selectively doped absorber layer into a completed device may yield a PCE of approximately 22%.

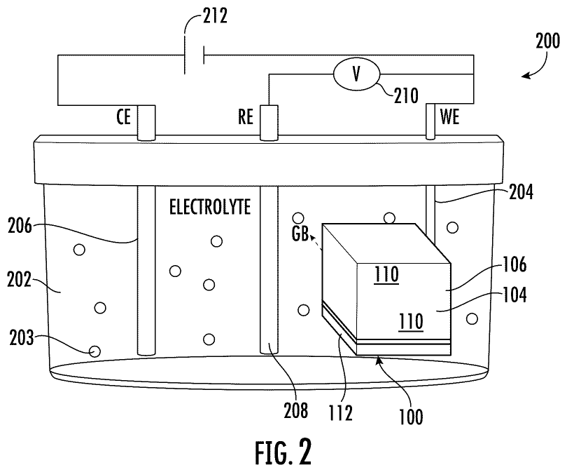

In some embodiments, electric-field-assisted selective grain-boundary doping is performed using an electrochemical cell 200, as illustrated in FIG. 2. The electrochemical cell includes an electrolyte solution 202 comprising one or more dopant species 203. The polycrystalline chalcogenide structure 102, supported on an electrically conductive substrate such as an FTO substrate 104 disposed on a transparent layer 106, is electrically coupled as a working electrode 204.

The electrochemical cell further includes a counter electrode 206 and, optionally, a reference electrode 208. An electrical potential is applied across the electrochemical cell using a voltage source 210, which in some embodiments may include or be powered by a battery 212. In some embodiments, electrodes 116 and 118 are positioned to establish an electric field across the polycrystalline chalcogenide structure during processing.

Upon application of the electric field, dopant species 203 within the electrolyte migrate toward the polycrystalline chalcogenide structure 102. Grain-boundary regions 112 exhibit higher electrical conductivity or enhanced charge-transport pathways under the applied potential relative to grain interiors 110. As a result, localized electric-field concentration and preferential current flow occur at grain-boundary regions 112, promoting selective incorporation of dopant material 114 into the grain boundaries.

The magnitude of the applied voltage and the duration of electric-field application are selected to promote selective grain-boundary doping while limiting bulk dopant incorporation and excessive surface deposition. In some embodiments, the electric-field-assisted process is performed, thereby reducing thermal budget and preserving the structural integrity of grains 108 and grain interiors 110.

Surface cleaning may include contacting the exposed surface with one or more chemical solutions selected to remove surface-deposited dopant material without substantially removing dopant material from grain-boundary regions. Non-limiting examples include diluted hydrochloric acid, ammonia solutions, ethanol, acetone, carbon disulfide, or combinations thereof. Cleaning conditions may be selected to preserve the underlying polycrystalline chalcogenide structure.

The selectively doped and surface-cleaned polycrystalline chalcogenide structure may serve as a precursor for subsequent thermal treatment to activate dopants and promote controlled diffusion into grain interiors.

Heating or annealing promotes diffusion of dopant material 114 from grain-boundary regions 112 into adjacent grain interiors 110, as illustrated in FIG. 1D. The temperature, duration, and ambient conditions of thermal treatment are selected to control dopant diffusion and activation. In some embodiments, thermal treatment is performed at temperatures lower than those required for conventional bulk diffusion doping processes, thereby limiting unintended back-surface doping or interface degradation.

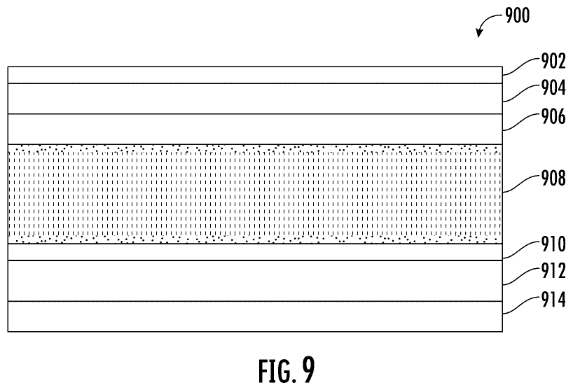

As schematically illustrated in FIGS. 1E and 9, the device includes a selectively doped polycrystalline chalcogenide absorber layer disposed between a front contact structure and a back contact structure. The front contact structure may include a transparent layer and a transparent conductive oxide, while the back contact structure includes one or more conductive layers electrically coupled to the absorber layer.

Electrodes 116 and 118 are disposed in electrical contact with the selectively doped polycrystalline chalcogenide to enable charge carrier collection. In some embodiments, the electrodes comprise carbon, gold, or other conductive materials suitable for photovoltaic device operation.

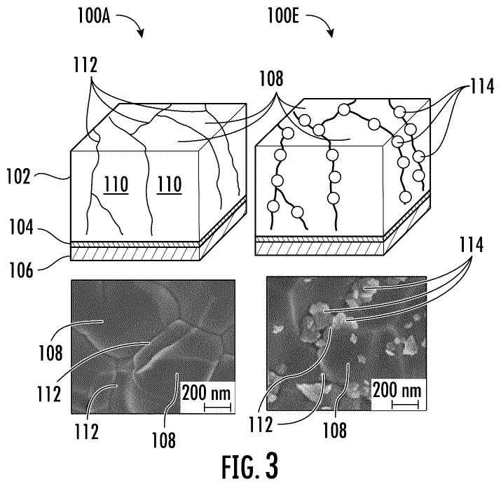

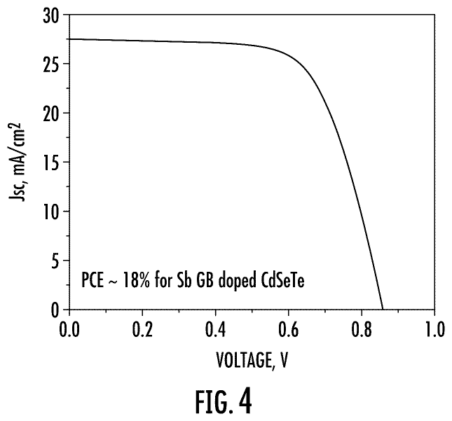

FIG. 3 schematically illustrates selective grain-boundary doping in accordance with some embodiments. Prior to doping, the polycrystalline chalcogenide 100A includes grains 108 and grain boundaries 112 with minimal dopant incorporation. FIG. 4 presents a representative current-voltage (J-V) curve for a CdSeTe photovoltaic device incorporating a selectively doped polycrystalline chalcogenide absorber layer.

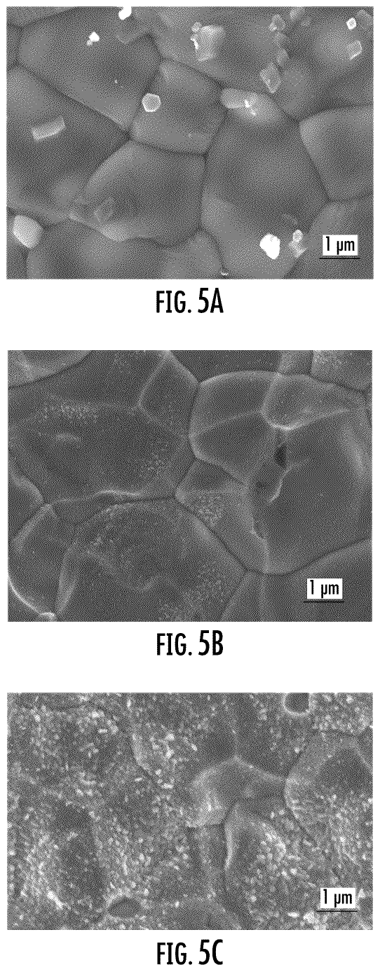

FIGS. 5A-5C show surface images of a polycrystalline CdTe structure different stages of electrochemical processing. FIG. 5A illustrates the surface prior to exposure to an electrolyte solution 202 containing dopant species 203. FIGS. 5B and 5C illustrate the surface after exposure to electrolyte solutions containing Sb-based and Bi-based dopant species 203, respectively. FIGS. 5A-5C support embodiments in which excess surface dopant may be subsequently removed while retaining dopant 114 at grain boundaries 112, thereby decoupling surface deposition effects from selective grain-boundary incorporation.

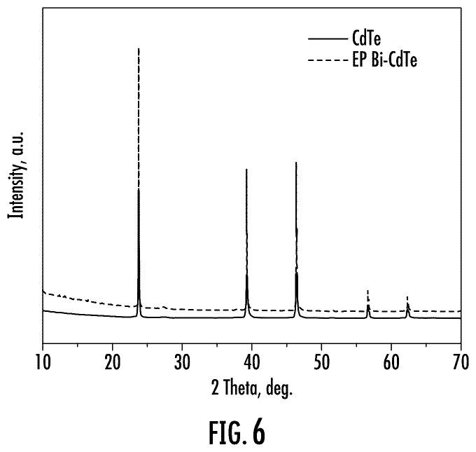

FIG. 6 shows X-ray diffraction (XRD) patterns representative of the crystalline structure of chalcogenide thin films processed in accordance with embodiments disclosed herein. FIG. 6 demonstrates that selective grain-boundary doping and associated electrochemical processing may be performed without substantially altering or degrading the crystalline structure of the polycrystalline chalcogenide material. Preservation of grain structure 108 and grain interiors 110 is desirable for maintaining device-grade material quality. FIG. 6 show the disclosed methods achieve selective dopant incorporation while maintaining structural characteristics suitable for photovoltaic operation.

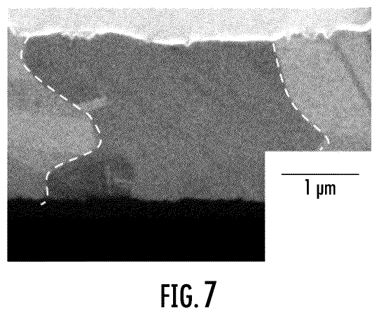

FIG. 7 shows a cross-sectional microstructural image illustrating selective localization of dopant 114 within grain-boundary regions 112 of a polycrystalline chalcogenide. FIG. 7 provides direct physical evidence that dopant incorporation may be concentrated at grain boundaries 112 relative to grain interiors 110 following electric-field-assisted electrochemical processing. In some embodiments, the spatial dopant distribution shown in FIG. 7 is established prior to any subsequent thermal treatment, and may serve as a precursor state for controlled dopant diffusion into grain interiors 110. F

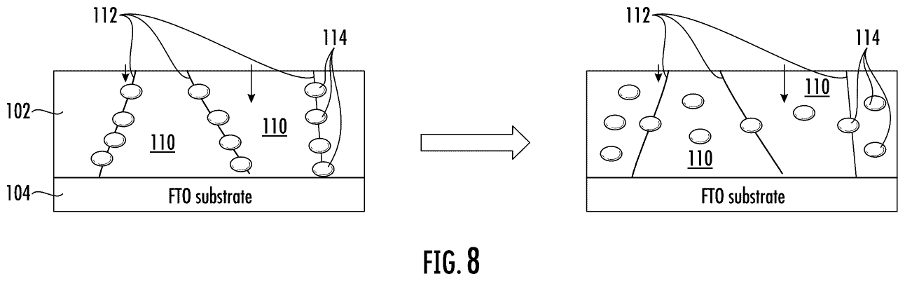

FIG. 8 illustrates a subsequent thermal treatment in accordance with some embodiments. After selective grain-boundary doping, the polycrystalline chalcogenide may be subjected to heating, annealing, or other thermal processing.

FIG. 9 illustrates an example device structure incorporating a selectively doped polycrystalline chalcogenide. In some embodiments, a film 900 includes a transparent layer 902, a electrically conductive layer 904, a buffer layer 906, and a selectively doped polycrystalline chalcogenide absorber layer 908. The absorber layer 908 includes grain boundaries 112 selectively doped with dopant 114.

In some embodiments, the device further includes a back contact layer 910 and a metal electrode 912 supported by a substrate 914. The selectively doped absorber layer 908 may provide improved charge carrier collection, reduced recombination at grain boundaries, and enhanced device performance.

Many additional implementations are possible. Further implementations are within the CLAIMS.

It will be understood that implementations of the preceding disclosure include but are not limited to the specific components disclosed herein, as virtually any components consistent with the intended operation may be utilized. Accordingly, for example, it should be understood that, while the drawings and accompanying text show and describe particular implementations, any such implementation may comprise any shape, size, style, type, model, version, class, grade, measurement, concentration, material, weight, quantity, and/or the like consistent with the intended operation.

The concepts disclosed herein are not limited to the specific embodiments shown herein. For example, it is specifically contemplated that the components included in particular embodiments may be formed of any of many different types of materials or combinations that can readily be formed into shaped objects and that are consistent with the intended operation of the disclosure. For example, the components may be formed of: rubbers (synthetic and/or natural) and/or other like materials; glasses (such as fiberglass), carbon-fiber, aramid-fiber, any combination therefore, and/or other like materials; elastomers and/or other like materials; polymers such as thermoplastics (such as ABS, fluoropolymers, polyacetal, polyamide, polycarbonate, polyethylene, polysulfone, and/or the like, thermosets (such as epoxy, phenolic resin, polyimide, polyurethane, and/or the like), and/or other like materials; plastics and/or other like materials; composites and/or other like materials; metals, such as zinc, magnesium, titanium, copper, iron, steel, carbon steel, alloy steel, tool steel, stainless steel, spring steel, aluminum, and/or other like materials; and/or any combination of the foregoing.

Furthermore, embodiments of the present disclosure may be manufactured separately and then assembled together, or any or all of the components may be manufactured simultaneously and integrally joined with one another. Manufacture of these components separately or simultaneously, as understood by those of ordinary skill in the art, may involve 3-D printing, extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled or removably coupled with one another in any manner, such as with adhesive, a weld, a fastener, any combination thereof, and/or the like for example, depending on, among other considerations, the particular material(s) forming the components.

In places where the description above refers to particular implementations, it should be readily apparent that a number of modifications may be made without departing from the spirit thereof and that these implementations may be applied to other implementations disclosed or undisclosed. The presently disclosed are, therefore, to be considered in all respects as illustrative and not restrictive.

What is claimed is:

1. A method of making a thin film for a solar cell, the method comprising:
treating a chalcogenide-based polycrystalline substrate with a solution comprising a chloride compound;
contacting the chalcogenide-based polycrystalline substrate with an electrolyte comprising at least one dopant;
applying an electric field to the chalcogenide-based polycrystalline substrate such that the at least one dopant is selectively disposed in grain boundaries of the chalcogenide-based polycrystalline substrate, and
heating the chalcogenide-based polycrystalline for a duration of from one second to one hour, thereby diffusing the at least one dopant from the grain boundaries to grain interiors of the chalcogenide-based polycrystalline substrate.

2. The method of claim 1, wherein the chalcogenide-based polycrystalline substrate comprises CdTe or CdSeTe.

3. The method of claim 1, wherein the chloride compound comprises CdCl₂.

4. The method of claim 1, wherein the at least one dopant comprises As, P, Sb, Bi, or Cu.

5. The method of claim 1, wherein the chalcogenide-based polycrystalline substrate comprises CdSeTe and the chloride compound comprises CdCl₂.

6. A method of making a thin film, the method comprising:
treating a cadmium-based polycrystalline substrate with a solution comprising a chloride compound;
contacting the cadmium-based polycrystalline substrate with an electrolyte comprising at least one dopant;
applying an electric field to the cadmium-based polycrystalline substrate such that the at least one dopant is selectively disposed in grain boundaries of the cadmium-based polycrystalline substrate, and
heating the cadmium-based polycrystalline substrate, thereby diffusing the at least one dopant from the grain boundaries to grain interiors of the cadmium-based polycrystalline substrate.

7. The method of claim 6, wherein the at least one dopant comprises As, P, Sb, Bi, or Cu.

8. The method of claim 7, wherein the cadmium-based polycrystalline substrate comprises CdTe and the chloride compound comprises CdCl₂.

9. The method of claim 8, wherein the cadmium-based polycrystalline substrate comprises CdSeTe.

10. The method of claim 6, wherein the cadmium-based polycrystalline substrate comprises a chalcogenide.

11. The method of claim 6, wherein the cadmium-based polycrystalline substrate is heated at a temperature between 200° C. and 400° C.

12. The method of claim 6, wherein heating the cadmium-based polycrystalline substrate is performed for a duration of from 1 second to 1 hour.

13. A method of selectively doping grain boundaries in a polycrystalline chalcogenide thin film, the method comprising:
treating a polycrystalline chalcogenide substrate with a chloride-containing solution;
contacting the polycrystalline chalcogenide substrate with an electrolyte comprising at least one dopant;
applying an electric field across the polycrystalline chalcogenide substrate such that the at least one dopant is driven into grain-boundary regions of the polycrystalline chalcogenide substrate; and
removing excess dopant material from a surface of the polycrystalline chalcogenide substrate.

14. The method of claim 13, wherein the polycrystalline chalcogenide substrate comprises CdTe or CdSeTe.

15. The method of claim 13, wherein the at least one dopant comprises As, P, Sb, Bi, or Cu.

16. The method of claim 13, wherein applying the electric field comprises applying a voltage of 0.1 to 10 volts for a duration of 0.1 to 100 seconds.

17. The method of claim 13, further comprising heating the polycrystalline chalcogenide substrate after removing the excess dopant material to diffuse the dopant from the grain-boundary regions into grain interiors.

18. The method of claim 13, wherein the chloride-containing solution comprises CdCl₂, NaCl, MgCl₂, NH₄Cl, or KCl.

19. The method of claim 13, wherein removing the excess dopant material comprises contacting the surface with an acid, base, or organic solvent selected from diluted hydrochloric acid, ammonia solution, ethanol, acetone, or carbon disulfide.

20. The method of claim 13, wherein the electrolyte comprises a group V halide.
